(19) United States
(12) Patent Application Publication
(10) Pub. No.: US 2019/0016022 A1
(43) Pub. Date: Jan. 17, 2019

(54) METHOD FOR MANUFACTURING MICROFLUIDIC DEVICE AND ASSOCIATED STRUCTURE

(71) Applicant: TAIWAN CARBON NANO TECHNOLOGY CORPORATION, MIAOLI COUNTY (TW)

(72) Inventors: Yu-Hsuan Liao, MIAOLI COUNTY (TW); Fang-Song Tsai, MIAOLI COUNTY (TW); Ya-Han Wu, MIAOLI COUNTY (TW); Chun-Hsien Tsai, MIAOLI COUNTY (TW); Ting-Chuan Lee, MIAOLI COUNTY (TW); Chun-Jung Tsai, MIAOLI COUNTY (TW)

(21) Appl. No.: 15/837,688

(22) Filed: Dec. 11, 2017

(30) Foreign Application Priority Data
Jul. 11, 2017 (TW) 106123175

(51) Int. Cl. B29C 39/02; B29C 33/38; B29C 33/58; B29C 33/60; B29C 39/00; G03F 7/00; B01L 3/00

(52) U.S. Cl. CPC B29C 39/026; B29C 33/3842; B29C 33/58; B29K 2083/00; B29C 39/003; G03F 7/0017; B01L 3/502707; B29C 33/60

(57) ABSTRACT

A method for manufacturing a microfluidic device includes following steps. A mold made of a glass material is provided. The mold has at least one hollow mold cavity and at least one blocking wall around the hollow mold cavity. The mold is disposed on a silicon substrate, which includes a formation surface corresponding to the hollow mold cavity and a microfluidic male mold protruding from the formation surface. Polydimethylsiloxane (PDMS) is poured into the hollow mold cavity and baked to harden the PDMS to form the microfluidic device. The microfluidic device has a microfluidic structure corresponding to the microfluidic male mold, and a height of a sidewall of the microfluidic device is between 3 mm and 30 mm. With the glass material of the mold, the microfluidic device having a sidewall height greater than 3 mm can be manufactured, preventing an insufficient suction force of a negative pressure.

### FIELD OF THE INVENTION

The present invention relates to a microfluidic device, and particularly to a method for manufacturing a microfluidic device and an associated structure.

### BACKGROUND OF THE INVENTION

With the booming developments of semiconductor technologies and biotechnologies, microfluidic reactors combining manufacturing technologies of microstructures and biomedical detection technologies are developed as one mainstream technical means for enhancing the quality of reaction products and enhancing process efficiency. Microfluidic reactors are extensively applied in the fields of chemical engineering, materials and pharmaceutical, and are essentials in the related fields.

For example, the U.S. Pat. No. 8,759,096, “Microfluidic Chip and Method Using the Same, discloses an application of microfluidics. The above disclosure includes a substrate and at least a tissue culture area. The substrate has a surface, and the at least one tissue culture area is formed on the surface of the substrate. The tissue culture area has a microfluidic channel formed by a plurality of connected geometrical structures having a predetermined depth. The microfluidic channel has an inlet and an outlet, which are at two ends of the microfluidic channel, respectively. At least an air-exchange hole is formed on the bottom of the microfluidic channel.

Further, polydimethylsiloxane (PDMS), featuring good optic penetration, high biocompatibility, and good chemical stability, is widely used as a substrate in microfluidics. However, current thick-mold photoresist or dry-mold technologies cannot yield a height of a sidewall of manufactured PDMS to be a height appropriate for generating a sufficient negative pressure. When acrylic is applied for manufacturing a mold, the PDMS overflows due to deformation of the acrylic after multiple baking processes and the coefficient thermal expansion, thus failing in achieving the requirement of small line widths and the repetitive industrial production requirement of mold stripping. In particular, when the height of the sidewall of a negative-pressure PDMS microfluid channel is smaller than a height appropriate for generating a sufficient negative pressure, the suction force of the negative force can be inadequate and hence applications are greatly limited, in a way that original design advantages of microfluids cannot be fully exercised. Therefore, there is a need for a solution for manufacturing a PDMS microfluidic channel having an appropriate height for generating a sufficient negative pressure.

### SUMMARY OF THE INVENTION

It is an object of the present invention to solve the issue of an inadequate suction force of a negative pressure caused by an unsatisfactory height of a sidewall of a conventional PDMS microfluidic channel.

To achieve the above object, the present invention provides a method for manufacturing a microfluidic device. The method of the present invention includes following steps.

In step S1, a mold made of a glass material is provided. The mold comprises at least one hollow mold cavity and at least one blocking wall around the hollow mold cavity. The blocking wall has a height greater than or equal to 3 mm.

In step S2, the mold is disposed on a silicon substrate. The silicon substrate includes a formation surface corresponding to the hollow mold cavity, and a microfluidic male mold protruding from the formation surface.

In step S3, unhardened PDMS is poured into the hollow mold cavity, and a baking process is performed to harden the PDMS to form the microfluidic device.

In step S4, the microfluidic device is removed from the hollow mold cavity and the silicon substrate. The microfluidic structure includes a microfluidic structure corresponding to the microfluidic male mold, and a height of a sidewall of the microfluidic device is between 3 mm and 30 mm.

To achieve the above object, the present invention further provides a microfluidic device manufactured by the foregoing method.

In one embodiment of the present invention, at least one corner of the hollow mold cavity of the mold is processed by a smoothing treatment to become a round corner.

In one embodiment of the present invention, after step S2, a mold release agent is applied on the hollow mold cavity and the formation surface.

In conclusion, compared to the prior art, the present invention provides following advantages.

1. In the present invention, the mold is made of a glass material, which has a coefficient of thermal expansion close to that of the silicon substrate, and so the levelness of the surfaces of the mold and the silicon substrate is maintained and deformation is eliminated even after multiple baking processes. Thus, the PDMS is prevented from overflowing during heating and baking, and subsequent trimming and shaping can be reduced.

2. In the present invention, the microfluidic device, manufactured through the mold made of a glass material, has a sidewall with a height appropriate for generating a sufficient negative pressure. Therefore, with respect to the structural design, a deeper vertical channel is achieved to generate a greater negative pressure, preventing the issue of an inadequate negative pressure.

3. In the present invention, at least one corner of the hollow mold cavity is processed by a smoothing treatment to become a round corner, and the microfluidic device manufactured through the mold correspondingly comprises a round corner. With the joint application of the mold release agent, the subsequent mold stripping is facilitated to accelerate the speed of mold stripping and manufacturing speed, while preventing damages of the microfluidic device.

### BRIEF DESCRIPTION OF THE DRAWINGS

FIG. 1 is a flowchart of steps of a process according to an embodiment of the present invention;

FIG. 2 is a two-dimensional schematic diagram of a mold according to an embodiment of the present invention;

FIG. 3A to FIG. 3F are schematic diagrams of a manufacturing process of a section along A-A in FIG. 2; and

FIG. 4 is a schematic diagram of a finished product according to an embodiment of the present invention.

### DETAILED DESCRIPTION OF THE PREFERRED EMBODIMENTS

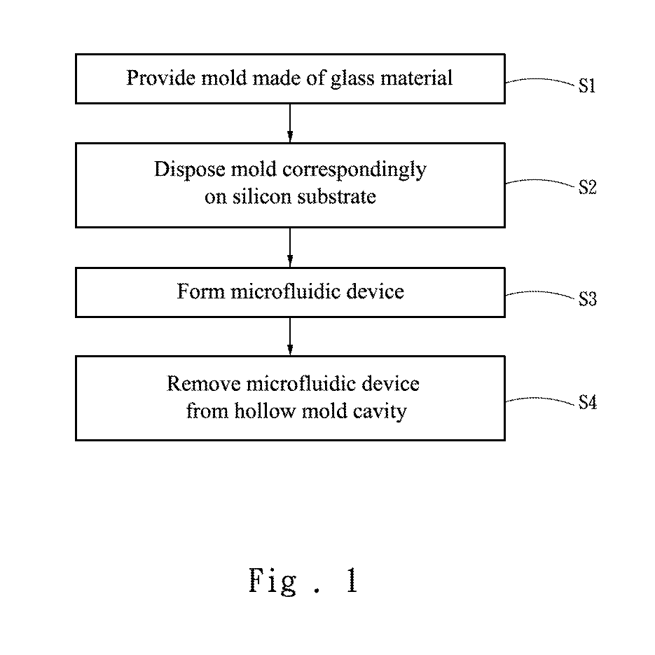

Referring to FIG. 1 to FIG. 4, the present invention provides a method for manufacturing a microfluidic device 40 and an associated structure. The microfluidic device 40 includes a microfluidic structure 41, and a sidewall having a height between 3 mm and 30 mm. The method includes following steps.

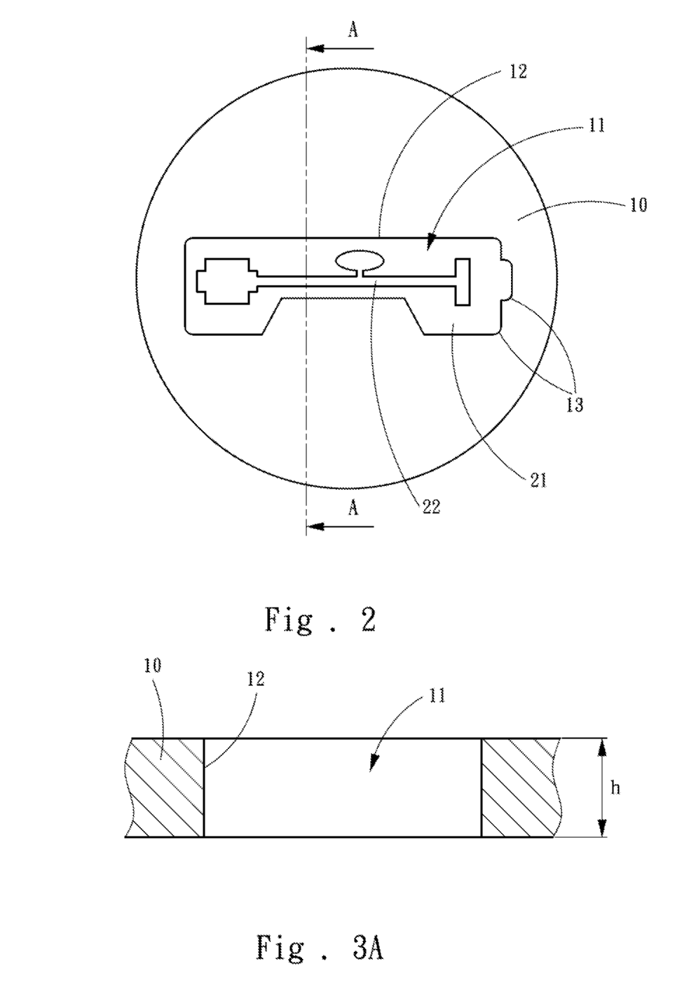

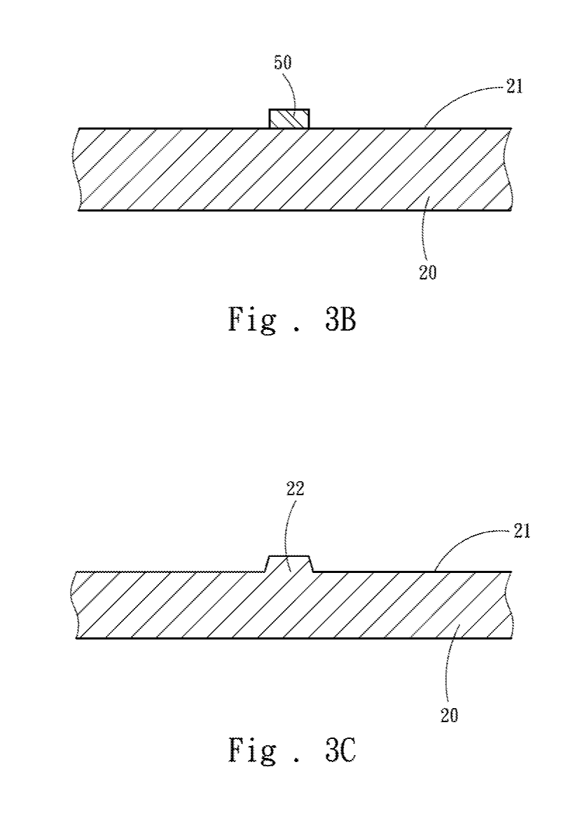

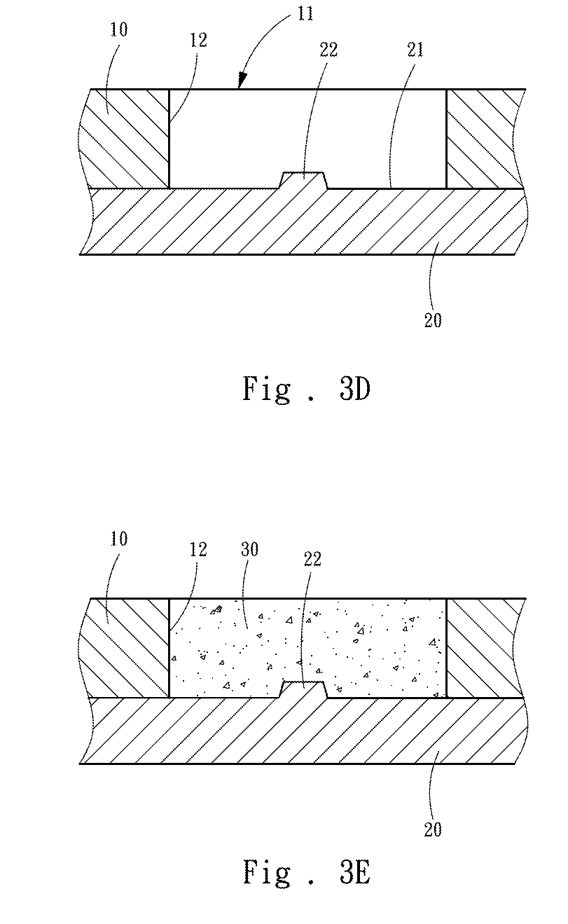

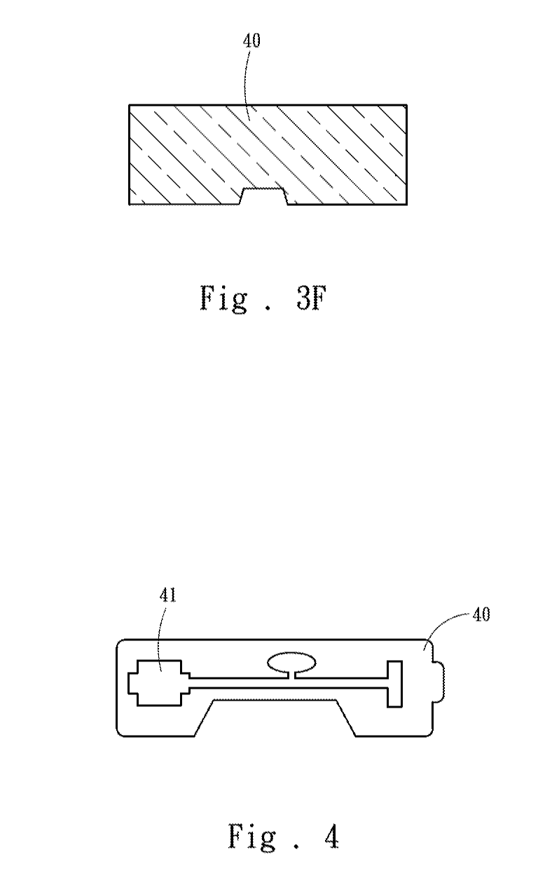

In step S1, as shown in FIG. 3A, a mold 10 is provided. The mold 10 is made of a glass material, and comprises at least one hollow mold cavity 11 and at least one blocking wall 12 around the hollow mold cavity 11. The blocking wall 12 has a height h greater than or equal to 3 mm. In this embodiment, there is only one hollow mold cavity 11 with one corresponding blocking wall 12. Another embodiment of the present invention may include two or more hollow mold cavities 11 with corresponding blocking walls 12.

Means for manufacturing the mold 10 may be laser processing, which is performed on the glass to form the mold 10 such that mold 10 has the hollow mold cavity 11 and the blocking wall 12 around the hollow mold cavity 11. The mold 10 may also be manufactured through other than laser processing. As shown in FIG. 2, at least one corner of the hollow mold cavity 11 is processed by a smoothing treatment to form a round corner 13. To facilitate subsequent mold stripping, a plurality of corners may be processed by the smoothing treatment to form a plurality of round corners 13. In one embodiment of the present invention, the smoothing treatment is a laser process, and other methods are also applicable in the present invention.

In step S2, as shown in FIG. 3B, FIG. 3C, FIG. 3D, the mold 10 is disposed on the silicon substrate 20. The silicon substrate 20 includes a formation surface 21 corresponding to the hollow mold cavity 11, and a microfluidic male mold 22 protruding from the formation surface 21. The silicon substrate 20 used in the present invention may be, for example but not limited to, a silicon wafer. Other appropriate silicon substrates are also applicable in the present invention.

In one embodiment of the present invention, the mold 10 and the silicon substrate 20 are in direct contact. More specifically, for example, a bond between the mold 10 and the silicon substrate 20 is produced through an anodic bonding method to combine the mold 10 and the silicon substrate 20. Thus, in the present invention, an additional adhesive layer formed by an adhesive material is not required between the mold 10 and the silicon substrate 20 as in the prior art, preventing the issue of possible overflown adhesive of an adhesive agent used in the prior art, as well as an alignment defect of the mold 10 and the silicon substrate 20 possibly caused by the adhesive layer.

With respect to the method for manufacturing the silicon substrate 20, as shown in FIG. 3B and FIG. 3C, a patterning photoresist mask 50 is formed on the formation surface 21 of the silicon substrate 20, the silicon substrate 20 is etched to form the microfluidic male mold 22 on the silicon substrate 20, and the patterning photoresist mask 50 is then removed. Means for forming the microfluidic male mold 22 is not limited to the above example. Further, the silicon substrate 20 may be manufactured before the manufacturing process of the present invention begins, and the manufacturing sequences of the mold 10 and the silicon substrate 20 are not limited to manufacturing the mold 10 before the silicon substrate 20.

After step S2, the method for manufacturing a microfluidic device of the present invention further includes following steps.

In step S2A, a mold release agent (not shown) is applied on the hollow mold cavity 11 and the formation surface 21 to facilitate the subsequent mold stripping. For example, the mold release agent may be at least one selected from a group consisting of a fluorine series mold release agent, a wax series mold release agent and a surfactant, and may be selected by one person skilled in the art depending on actual application requirements.

In step S3, as shown in FIG. 3E, unhardened PDMS 30 is poured into the hollow mold cavity 11, and baking is performed to harden the PDMS 30 to form a microfluidic device 40 (shown in FIG. 3F). Step S3 further includes following steps.

In step S3A, the PDMS 30 is manufactured. More specifically, a polymer material and a hardening agent are mixed to form the PDMS 30, which is left to stand for about 10 to 30 minutes to remove a part of the bubbles. Further, for example but not limited to, the weight ratio of the polymer material and the hardening agent is between 8:1 and 12:1. In one embodiment of the present invention, for example but not limited to, the polymer material may be polysiloxane, and the hardening agent may be a fatty amine, an alicyclic amine, an aromatic amine, or a polyamide.

In step S3B, the unhardened PDMS 30 is poured into the hollow mold cavity 11 and placed in a negative-pressure environment to stand until the bubbles in the PDMS 30 float and burst.

In step S3C, baking is performed to harden the PDMS 30 to form the microfluidic device 40. In one embodiment, baking may be performed at a baking temperature between 100° C. and 120° C. for a baking time between one-half hour and two hours. The baking temperature and the baking time may differ according to manufacturing processes, and are not limited to the above values. In step S4, as shown in FIG. 3F and FIG. 4, the microfluidic device 40 is removed from the hollow mold cavity 11 and the silicon substrate 20. The microfluidic device 40 includes a microfluidic structure 41 corresponding to the microfluidic male mold 22. Because the levelness of the surfaces of the mold 10 and the silicon substrate 20 is maintained and the two have similar coefficients of thermal expansion, deformation is eliminated even after multiple baking processes. Thus, the PDMS 30 is prevented from overflowing during heating and baking, and subsequent trimming and shaping can be reduced. Further, it is discovered experimentally that, the microfluidic device 40, having a sidewall with a height of 4 mm, manufactured by the method of the present invention needs only 3 minutes to absorb 10 μm of fluid into the cavity of the microfluidic device 40. In contrast, when the same test is carried out on the microfluidic device 40 having a sidewall with a height of 2 mm, 6 minutes is needed to absorb the same amount of fluid into the cavity thereof.

In summary, compared to the prior art and a conventional microfluidic device manufactured using the prior art, the method for manufacturing a microfluidic device of the present invention and the microfluidic device manufactured using the same at least provide following advantages.

1. In the present invention, the mold is made of a glass material, which has a coefficient of thermal expansion close to that of the silicon substrate, and so the levelness of the surfaces of the mold and the silicon substrate is maintained and deformation is eliminated even after multiple baking processes. Thus, the PDMS is prevented from overflowing during heating and baking, and subsequent trimming and shaping can be reduced.

2. In the present invention, the microfluidic device, manufactured through the mold made of a glass material, has a sidewall with a height appropriate for generating a sufficient negative pressure. Therefore, with respect to the structural design, a deeper vertical channel is achieved to generate a greater negative pressure, eliminating the issue of an inadequate negative pressure.

3. In the present invention, using the mold release agent applied, subsequent mold striping is facilitated to accelerate the speed of mold stripping and manufacturing speed, while preventing damages of the microfluidic device.

4. In the present invention, at least one corner of the hollow mold cavity is processed by a smoothing treatment to become a round corner, and the microfluidic device manufactured through the mold correspondingly comprises a round corner. With the application of the mold release agent, the subsequent mold stripping is facilitated to accelerate the speed of mold stripping and manufacturing speed, while preventing damages of the microfluidic device.

1. A method for manufacturing a microfluidic device, comprising:
S1: providing a mold made of a glass material, the mold having at least one hollow mold cavity and at least one blocking wall around the hollow mold cavity, the blocking wall having a height greater than or equal to 3 mm;
S2: disposing the mold on a silicon substrate, the silicon substrate comprising a formation surface corresponding to the hollow mold cavity and a microfluidic male mold protruding from the formation surface;
S3: pouring unhardened polydimethylsiloxane (PDMS) into the hollow mold cavity, and performing baking to harden the PDMS to form the microfluidic device; and
S4: removing the microfluidic device from the hollow mold cavity and the silicon substrate, the microfluidic device comprising a microfluidic structure corresponding to the microfluidic male mold, and a height of a sidewall of the microfluidic structure being between 3 mm and 30 mm.

2. The method for manufacturing a microfluidic device of claim 1, wherein a process for manufacturing the silicon substrate comprises:
forming a patterning photoresist mask on the formation surface of the silicon substrate, and etching the silicon substrate to form the microfluidic male mold on the silicon substrate; and
removing the patterning photoresist mask.

3. The method for manufacturing a microfluidic device of claim 1, after step S2, further comprising:
S2A: applying a mold release agent on the hollow mold cavity and the formation surface, the mold release agent being at least one selected from a group consisting of a fluorine series mold release agent, a wax series mold release agent and a surfactant.

4. The method for manufacturing a microfluidic device of claim 1, wherein step S3 further comprises:
S3A: mixing a polymer material and a hardening agent to form the PDMS, a weight ratio of the polymer material and the hardening agent being between 8:1 and 12:1;
S3B: pouring the unhardened PDMS into the hollow mold cavity and placing the same in a negative-pressure environment, to cause bubbles in the PDMS to float and burst; and
S3C: performing baking to harden the PDMS to form the microfluidic device.

5. The method for manufacturing a microfluidic device of claim 4, wherein the polymer material is polysiloxane.

6. The method for manufacturing a microfluidic device of claim 1, wherein the mold and the silicon substrate are in direct contact.

7. The method for manufacturing a microfluidic device of claim 1, wherein a bond between the mold and the silicon substrate is produced through an anodic bonding method to combine the mold and the silicon substrate.

8. The method for manufacturing a microfluidic device of claim 1, wherein at least one corner of the hollow mold cavity of the mold is processed by a smoothing treatment to become a round corner.

9. The method for manufacturing a microfluidic device of claim 8, wherein the smoothing treatment is performed by a laser process.

10. A microfluidic device, manufactured by the method of claim 1.
